(19) United States
(12) Patent Application Publication
(10) Pub. No.: US 2016/0209311 A1
(43) Pub. Date: Jul. 21, 2016

(54) RHEOLOGICAL MEASUREMENT DEVICE WITH TORQUE SENSOR

(71) Applicants: Tiomothy Ian BROX, Mt. Cook, Wellington (NZ); Petrik GALVOSAS, Karori, Wellington (NZ); VICTORIA LINK LIMITED, Kelburn, Wellington (NZ)

(72) Inventors: Timothy Ian BROX, Mt. Cook, Wellington (NZ); Petrik GALVOSAS, Karori, Wellington (NZ)

(73) Assignee: VICTORIA LINK LIMITED, Kelburn, Wellington (NZ)

(21) Appl. No.: 14/915,110

(22) PCT Filed: Aug. 12, 2014
(86) PCT No.: PCT/NZ2014/000168

§ 371 Date: Feb. 26, 2016

(30) Foreign Application Priority Data
Aug. 28, 2013 (NZ) 614797

(51) Int. Cl. G01N 11/14; G01N 24/08; G01R 33/30

(52) U.S. Cl. CPC G01N 11/14; G01R 33/307; G01N 24/08

(57) ABSTRACT

The invention relates to a rheological measurement device adapted for use in a bore of an NMR magnet. The measurement device comprises a drive shaft, a drive shaft housing in which the drive shaft is located, and a torque sensor directly or indirectly attached to the drive shaft. The torque sensor is positioned substantially in line with the drive shaft.

### TECHNICAL FIELD The invention relates to rheological measurement devices for use in rheology and in Rheo-NMR.

### BACKGROUND OF THE INVENTION

Nuclear magnetic resonance (NMR) spectroscopy and velocimetry have become unique tools for the investigation of complex fluids under shear. Past improvements have enriched the information learned about soft matter through Rheo-NMR experiments. Rheo-NMR is the study of fluids under shear flow using NMR methods and is primarily used for soft matter research. Rheo-NMR provides the ability to study materials under shear (including those that are optically opaque) and allows dynamic phenomenon, such as slip, shear thinning, shear banding, yield stress behaviour, nematic director alignment, and shear-induced mesophase reorganisation, to be identified and analysed.

Measurement devices currently used in NMR machines for Rheo-NMR typically comprise a drive shaft to which an analysis device, such as a shear cell, can be attached. The shear cell contains a sample of soft matter material and the sample's response to deformation can be analysed using the NMR machine. A motor is mounted separately to the drive shaft and is coupled to the drive shaft to cause the drive shaft to rotate along its axle. A controller is used to set the speed at which the drive shaft rotates.

However, known commercially available Rheo-NMR devices do not include a torque sensor, which prevents these devices from measuring global rheological parameters, such as shear stress, during NMR experiments. Without simultaneous measures of both NMR and global rheological parameters it is difficult to compare NMR measurements of molecular dynamics with a material's torque response to imposed strain.

It is therefore an object of the invention to provide a measurement device for use in Rheo-NMR experiments that comprises a torque sensor to go at least some way toward overcoming one or more disadvantages of the prior art, or that at least provides a useful alternative.

### SUMMARY OF THE INVENTION

In a first aspect, the invention provides a rheological measurement device adapted for use in a bore of an NMR magnet, the measurement device comprising a drive shaft, a drive shaft housing in which the drive shaft is located, and a torque sensor directly or indirectly attached to the drive shaft, wherein the torque sensor is positioned in line with the drive shaft.

In one form, a first end of the torque sensor is indirectly attached to the drive shaft and drive shaft housing by a torque sensor coupling.

A shear cell may be directly or indirectly attached to the torque sensor.

In one form, the measurement device further comprises a drive shaft extension system comprising a second torque sensor coupling, and a drive shaft located within an extension housing, wherein the second torque sensor coupling attaches a second end of the torque sensor to the extension drive shaft and the extension housing.

A shear cell may be attached to the second drive shaft.

Preferably, the measurement device comprises a wire guide within which wires to connect the torque sensor to a control system can be positioned.

In a second aspect, the invention provides a rheology unit comprising a measurement device according to the first aspect of the invention and further comprising a drive system comprising a motor coupled to the drive shaft and adapted to rotate the drive shaft.

Preferably, the drive system further comprises a control system comprising a positioning sensor for identifying the orientation of the drive shaft in relation to a drive shaft housing. In one form, the positioning sensor is an optical encoder.

As used in this specification, the words “comprises”, “comprising”, and similar words, are not to be interpreted in an exclusive or exhaustive sense. In other words, they are intended to mean “including, but not limited to”.

### BRIEF DESCRIPTION OF THE FIGURES

Preferred forms of the invention will now described in relation to the accompanying drawings, in which:

FIG. 1 is an exploded view of one form of rheology unit according to one form of the invention;

FIG. 2a is a perspective view of the rheology unit of FIG. 1 in assembled form;

FIG. 2b is a side view of the rheology unit of FIG. 2a ;

FIG. 2c is a cross-sectional side view of the rheology unit taken along line A-A of FIG. 2b ;

FIG. 3 is a perspective view of one form of drive shaft;

FIG. 4a is a perspective view of one form of motor mount;

FIG. 4b is a side view of the motor mount of FIG. 4a;

FIG. 4c is another side view of the motor mount of FIG. 4a;

FIG. 4d is a cross-sectional side view of the motor mount taken along lines A-A of FIG. 4c;

FIG. 5a is a perspective view of one form of drive shaft housing for the drive shaft of FIG. 3;

FIG. 5b is a side view of the drive shaft housing of FIG. 5a;

FIG. 5c is a cross-sectional side view of the drive shaft housing taken along lines A-A of FIG. 5b;

FIG. 6a is a perspective view of one form of collar;

FIG. 6b is a side view of the collar of FIG. 6a;

FIG. 6c is another side view of the collar of FIG. 6a;

FIG. 7a is a perspective view of a first torque sensor coupling;

FIG. 7b is a side view of the torque sensor coupling of FIG. 7a;

FIG. 7c is a cross-sectional side view of the torque sensor coupling taken along line A-A of FIG. 7b;

FIG. 7d is a top view of the torque sensor coupling of FIG. 7a;

FIG. 8a is a perspective view of one form of torque sensor;

FIG. 8b is a side view of the torque sensor of FIG. 8a;

FIG. 8c is a cross-sectional side view of the torque sensor taken along line A-A of FIG. 8b;

FIG. 9a is a perspective view of a cup of one form of shear cell;

FIG. 9b is a side view of the cup of FIG. 9a;

FIG. 9c is a cross-sectional side view of the cup taken along line A-A of FIG. 9b;

FIG. 10a is a perspective view of a spindle to be used with the cup of FIG. 9a;

FIG. 10b is a side view of the spindle of FIG. 10a;

FIG. 10c is a cross-sectional side view of the spindle taken along line A-A of FIG. 10b;

FIG. 11 is an exploded view of another form of rheology unit according to the invention;

FIG. 12a is a perspective view of the rheology unit of FIG. 11 in assembled form;

FIG. 12b is a side view of the rheology unit of FIG. 12a;

FIG. 12c is a cross-sectional side view of the rheology unit taken along line A-A of FIG. 12b;

FIG. 13a is perspective view of one form of a second torque sensor coupling;

FIG. 13b is a side view of the second torque sensor coupling of FIG. 13a;

FIG. 13c is a cross-sectional side view of the second torque sensor coupling taken along line A-A of FIG. 13b;

FIG. 14a is a perspective view of one form of drive shaft extension;

FIG. 14b is a side view of the drive shaft extension of FIG. 14a;

FIG. 15a is a perspective view of one form of extension housing;

FIG. 15b is a side view of the extension housing of FIG. 15a;

FIG. 15c is another side view of the extension housing of FIG. 15a;

FIG. 15d is a cross-sectional side view of the extension housing taken along line A-A of FIG. 15c;

FIG. 16a is a perspective view of a cup for another form of shear cell;

FIG. 16b is a side view of the cup of FIG. 16a;

FIG. 16c is a cross-sectional side view of the cup taken along line A-A of FIG. 16b;

FIG. 17a is a perspective view of a spindle to be used with the cup of FIG. 16a;

FIG. 17b is a side view of the spindle of FIG. 17a; and

FIG. 17c is a cross-sectional side view taken along line A-A of FIG. 17b.

### DETAILED DESCRIPTION

The invention relates to a rheology unit for measuring rheology samples within a bore of an NMR machine that uses a high field (approximately 250 MHz or greater) super conducting NMR magnet. The invention also relates to a rheological measurement device for the rheology unit. The rheological measurement device is adapted to fit within and to be used within a bore of an NMR magnet

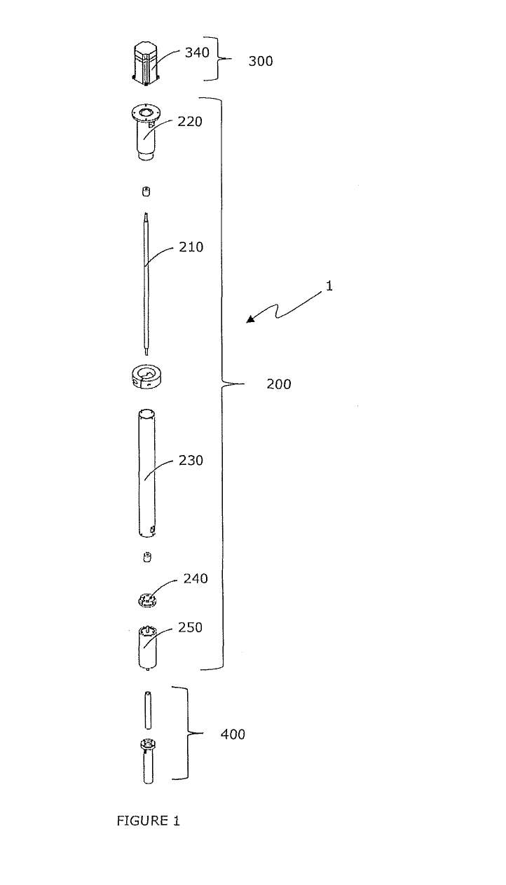

As shown in FIG. 1, the rheology unit 1 comprises a measurement device 200 and a drive system 300. The rheology unit also comprises an analysis device, such as a shear cell 400, that is used to hold a sample and can be attached to the measurement device for the sample to be analysed.

The measurement device comprises a torque sensor so that the torque response of the sample can be readily measured when the rheology unit is in use. The measurement device is adapted to be placed within the bore of an NMR magnet allowing for simultaneous NMR and torque measurements.

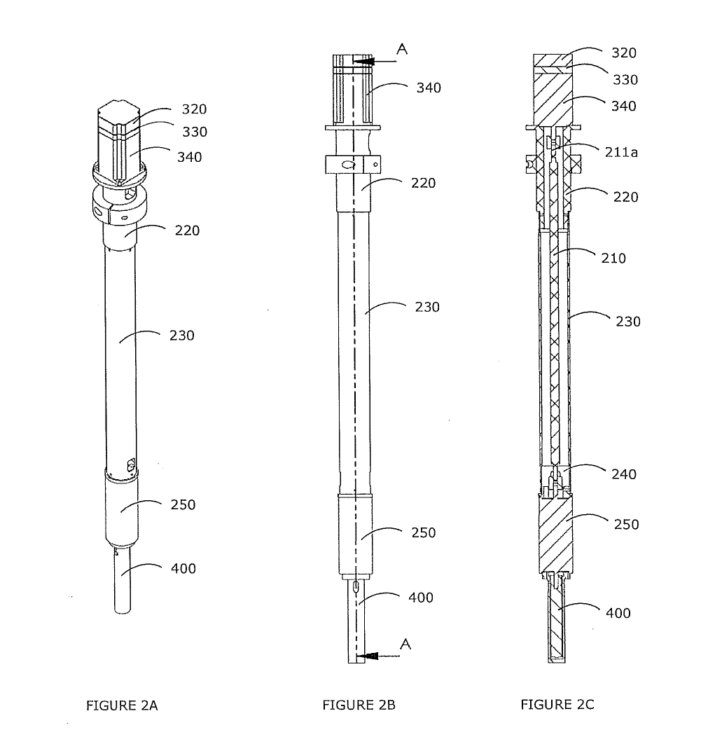

As shown in FIGS. 1 and FIGS. 2a to 2c, the measurement device 200 comprises a drive shaft 210, which is driven by a drive system 300 comprising a motor 340 having an output shaft coupled to a first end of the drive shaft. The drive system may also comprise a control system 320 to which the motor is connected. The control system controls the frequency and direction of rotation of the output shaft of the motor. The motor can therefore cause the drive shaft to rotate clockwise and anti-clockwise (as desired) along the longitudinal axis of the drive shaft at various frequencies of rotation.

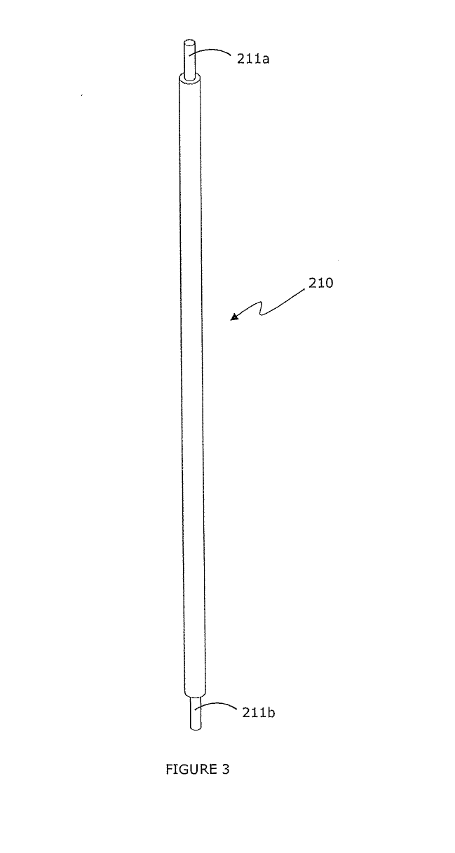

The motor may be a servo motor, a stepper motor, a servo-stepper motor, or any other suitable motor. In one form, the drive system 300 comprises a dual shaft stepper motor 340 having a first output shaft that is coupled to a first end 211a of the drive shaft, as shown in FIGS. 2a to 2c, and FIG. 3. The drive system also comprises a control system 320 and a positioning sensor 330 connected to the second shaft of the stepper motor. The positioning sensor may be a high resolution optical encoder that reads the orientation of the drive shaft in relation to a drive shaft housing. The positioning sensor, or optical encoder, communicates this information to the motor control system 320. The positioning sensor, motor, and control system operate in a closed feedback loop that allows for prompt and accurate adjustment of the rotational frequency and direction of the drive shaft to satisfy operating criteria. In this way, it is possible to ensure that the drive shaft is in the correct position relative to the drive shaft housing at set time intervals to suit the parameters of the experiment.

Where a stepper motor is used, fine rotational control Is also provided for in the closed feedback loop system. For example, tests have shown that, using feedback from a high resolution optical encoder, the stepper motor can be programmed to rotate the drive shaft in 0.05° steps.

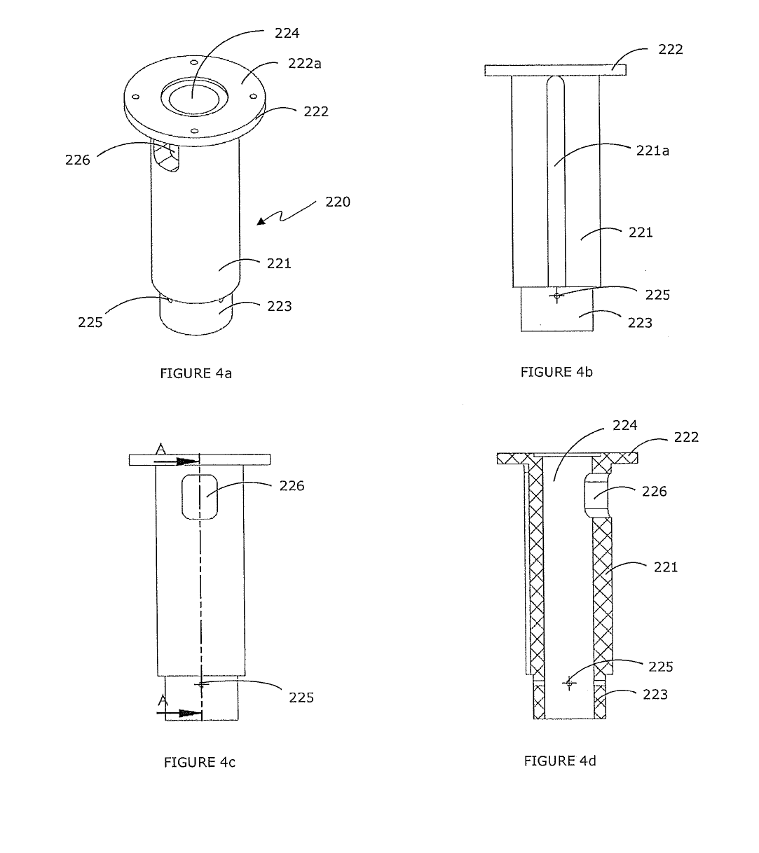

In one form, the motor 300 is mounted on the measurement device. In particular, the motor is mounted on a motor mount 220 that is attached to a drive shaft housing 230 within which the drive shaft 210 is located. In the embodiment shown in FIGS. 2a to 2c and 4a to 4d, the motor mount 220 comprises a cylindrical body 221 having an exterior surface along which a wire guide channel 221a extends. An access aperture 226 may be provided in the body of the motor mount to allow access to the coupling between the motor and the first end of the drive shaft.

In the embodiment shown best in FIGS. 4a to 4d, the motor mount also comprises a flanged collar 222 located at a first end of the motor mount body. The flanged collar 222 comprises a first face 222a on which the motor 300 is mounted. In one embodiment, the opposing second end of the motor mount comprises an attachment block 223 that projects from the motor mount body 221. A centrally located bore 224 extends along the length of the motor mount, through the collar 222, body 221 and block 223.

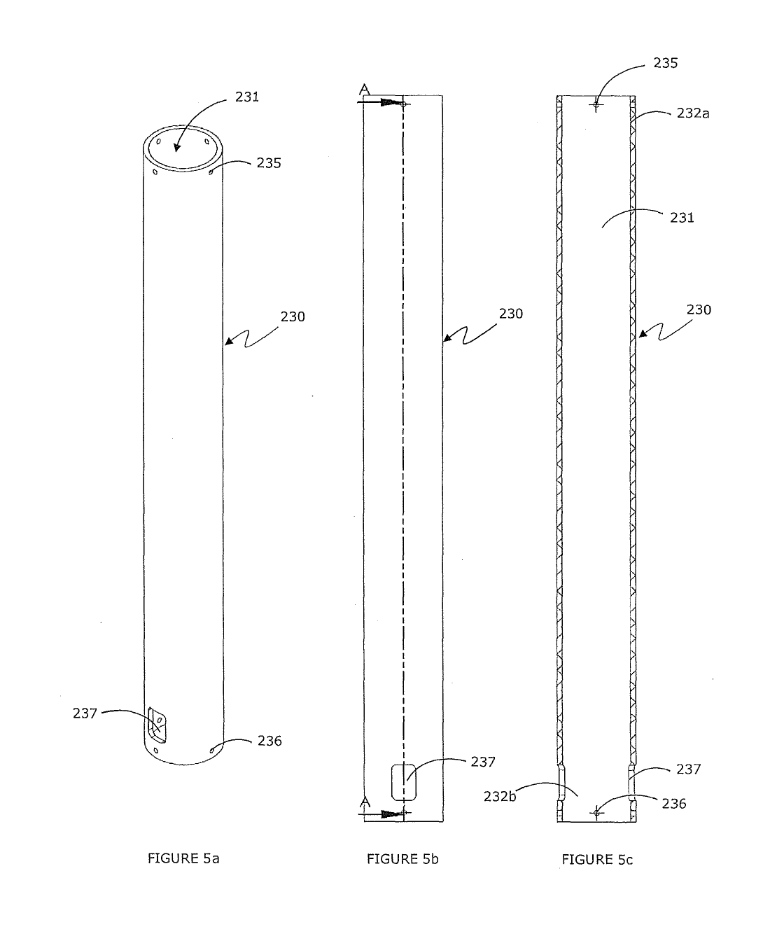

Preferably, the motor mount comprises attachment means for attaching to the drive shaft housing 230. In one form, the attachment means comprise a set of threaded apertures 225 through which attachment pins, such as screws, can be inserted to attach the housing 230 to the motor mount, as described below. In particular, the second end of the motor mount 220 is adapted to attach to the substantially cylindrical drive shaft housing 230, shown in FIGS. 5a to Sc. The drive shaft housing 230 has a central bore 231 that is aligned with the central bore 224 of the motor mount. The attachment block 223 of the motor mount fits within a first end 232a of the bore 231 of the drive shaft housing. The block 223 is positioned so that the apertures 225 of the motor mount align with apertures 235 formed at the first end of the drive shaft housing. Attachment pins, screws, or the like are placed through the aligned apertures 225, 235 and held in place to couple the drive shaft housing to the motor mount.

In another form, the first end of the drive shaft housing may be threaded and adapted to mesh with a threaded region provided on the attachment block of the motor mount so that the drive shaft housing can be screwed onto the motor mount. It should be appreciated that other ways of attaching the motor mount to the drive shaft housing may be used instead, as would be apparent to a person skilled in the art.

The drive shaft 210 is positioned within the bore 231 of the drive shaft housing. Preferably, the drive shaft housing is substantially cylindrical and preferably its bore is also substantially cylindrical.

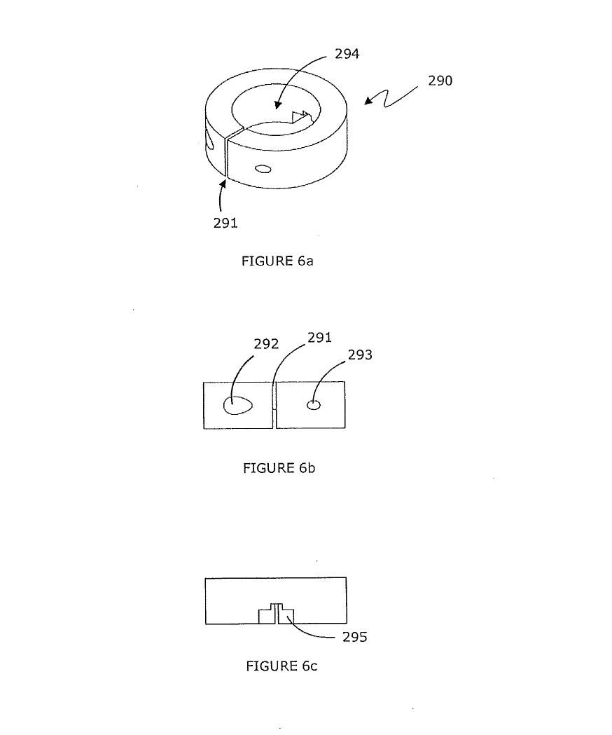

The measurement device 200 may also comprise a collar 290 that clamps around a portion of the drive shaft housing and is adapted to control the depth at which the rheology unit can be fitted within a bore of an NMR machine. The collar comprises a substantially ring-shaped body having a slit opening 291 and a pair of substantially opposing threaded apertures 292 and 293 on either side of the slit 291, as shown in FIGS. 6a to 6c. The housing collar 290 comprises a central bore 294 within which the drive shaft housing 230 is located. The housing collar is adapted to substantially surround the drive shaft housing and can slide up and down the drive shaft housing until it reaches a desired position. The slit 291 allows the housing collar to be compressed so that the slit closes and the collar clamps around a portion of the drive shaft housing when the collar is in the desired position. The collar is held in the clamping position by a screw or the like that engages with threaded interiors of the apertures 292 and 293 to hold the collar closed. Alternatively, the collar may be held in the clamping position by any other suitable means.

The collar forms an outwardly projecting lip around the drive shaft housing and is used to set the insertion depth of the drive shaft into the bore of the magnet of an NMR machine. Therefore, by adjusting the position of the collar along the length of the drive shaft housing, it is possible to adjust the depth at which the rheology unit is placed in an NMR machine. The housing collar also comprises a recess 295 that is adapted to mate with one or more projections located in the bore of a typical NMR machine to hold the rheology unit in position within the machine.

The measurement device 200 further comprises a torque sensor 250, which may be adapted to be directly attached to the drive shaft housing or may be attached to the housing using a coupling or the like that is adapted to couple the torque sensor to the drive shaft 210.

In one form, the measurement device comprises a torque sensor coupling 240 for indirectly coupling the torque sensor 250 to the drive shaft housing 230.

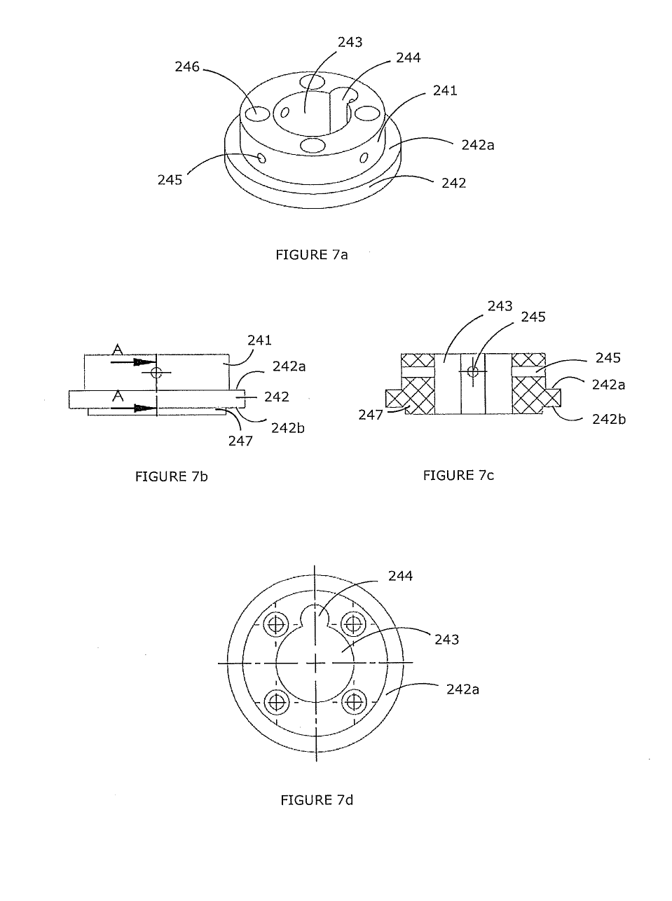

One form of torque sensor coupling 240 is shown in FIGS. 7a to 7d. The coupling 240 comprises an attachment shaft 241, a locating block 247, and a collar 242 located at one end of the attachment shaft 241 and between the attachment shaft and locating block 247. The attachment shaft 241 is substantially cylindrical and is dimensioned to fit within the bore 231 at the second end of the drive shaft housing. The collar 242 comprises a first surface 242a that faces in the direction of the attachment shaft, The collar also comprises an opposing second surface 242b that faces in the direction of the locating block 247, as shown in FIGS. 7b and 7c. A centrally located bore 243 extends through the centre of the first torque sensor coupling 240, through the attachment shaft, collar, and locating block, as shown best in FIGS. 7a and 7c. A wire guide in the form of a channel 244 extends along the length of the bore 243.

Preferably, the torque sensor coupling 240 comprises first attachment means for attaching the coupling to corresponding attachment means provided at a second end 232b of the drive shaft housing 230. In one form, as shown best in FIGS. 7a to 7c, the first attachment means of the torque sensor coupling comprise one or more apertures 245 located on an outer cylindrical wall of the attachment shaft 241. The torque sensor coupling is fitted to the second end of the drive shaft housing so that the attachment shaft fits within the bore of the drive shaft housing and so that the one or more apertures 245 align with one or more corresponding apertures 236 provided at the second end 232b of the drive shaft housing 230. A pin, screw or the like (not shown) is positioned within each pair of aligned apertures 245, 236 and is held in place to attach the first torque sensor coupling to the drive shaft housing. In another form, the attachment shaft may comprise a threaded region that is adapted to mesh with a threaded region provided on the second end of the drive shaft housing. It should be appreciated that other suitable forms for attaching the torque sensor coupling to the drive shaft housing may be used instead.

The torque sensor coupling and drive shaft housing are preferably positioned so that the edge of the second end of the drive shaft housing abuts the first surface 242a of the torque sensor coupling collar 242. It is also preferable that the collar has a substantially circular periphery and a diameter substantially equal to the diameter of the drive shaft housing to form a substantially flush join along the outer surface of the measurement device.

The torque sensor coupling 240 also comprises second attachment means for attaching the coupling to the torque sensor 250. Any suitable attachment means may be used. In one form, the second attachment means comprise one or more apertures 246 that extend between the end surface of the attachment shaft 241 and the end surface of the locating block 247. The apertures 246 are adapted to align with one or more corresponding apertures 256 located at a first end of the torque sensor, as shown in FIG. 7a. A pin, screw, or the like (not shown) is positioned within each pair of aligned apertures 246, 256 and is held in place to attach the torque sensor coupling to the torque sensor. In this way, the torque sensor coupling attaches the drive shaft housing to the torque sensor. However, it is envisaged that alternative forms of attachment means may be used to attach the drive shaft housing to the torque sensor without departing from the invention. For example, the torque sensor may comprise a threaded region for attaching directly to the threaded region of the drive shaft housing.

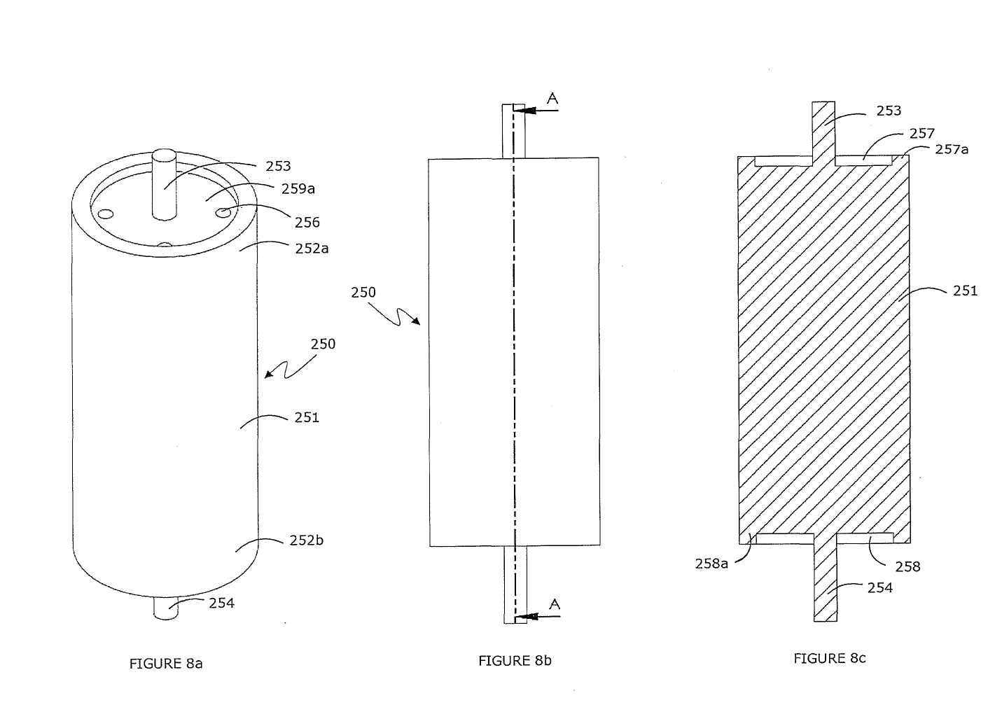

One form of torque sensor 250 is shown in FIGS. 8a to 8c. The sensor 250 comprises a body 251, which is preferably substantially cylindrical and preferably has a diameter substantially equal to the diameter of the drive shaft housing and the collar of the first torque sensor coupling. The body of the torque sensor has a first end 252a and an opposing second end 252b. A first input shaft 253 extends from the first end 252a of the sensor 250 and a second input shaft 254 extends from the second end 252b of the sensor. The first input shaft 253 is coupled to a second end 211b of the drive shaft 210 to attach the torque sensor 250 to the drive shaft.

Preferably, a first recess 257 is formed in the end face of the first end 252a of the body of the torque sensor. The first recess is defined by a surrounding wall 257a that follows the periphery of the first end of the torque sensor body. The first recess is adapted to mate with the locating block 247 of the first torque sensor coupling so that the locating block 247 is received within the first recess. As described above, one or more apertures 256 may be provided within the first recess to align with the one or more corresponding apertures 246 provided on the first torque sensor coupling 240 to attach the first torque sensor coupling to the torque sensor.

Preferably, the couplings between the motor, first drive shaft, and torque sensor are selected to correct any misalignment between these parts.

The torque sensor is electrically connected to the control system and/or to a reader or interface (not shown). In particular, wires from the torque sensor pass from the first end 252a of the body of the torque sensor, through the wire guide channels 244 and 221 and through the bore of the drive shaft housing (or along the exterior of the drive shaft housing) to the control system, reader and/or interface. In effect, the wire guide channels and the bore of the drive shaft housing (or along the exterior of the drive shaft housing) form a continuous wire guide.

The torque sensor comprises attachment means to attach the torque sensor to a shear cell. The torque sensor may be adapted to attach to a shear cell either directly or indirectly.

In one form, the torque sensor attachment means comprises a second recess 258 formed in the end face of the second end 252b of the body of the torque sensor. The second recess is defined by a surrounding wall 258a that follows the periphery of the second end of the torque sensor body. The second recess is adapted to receive a first end of a shear cell.

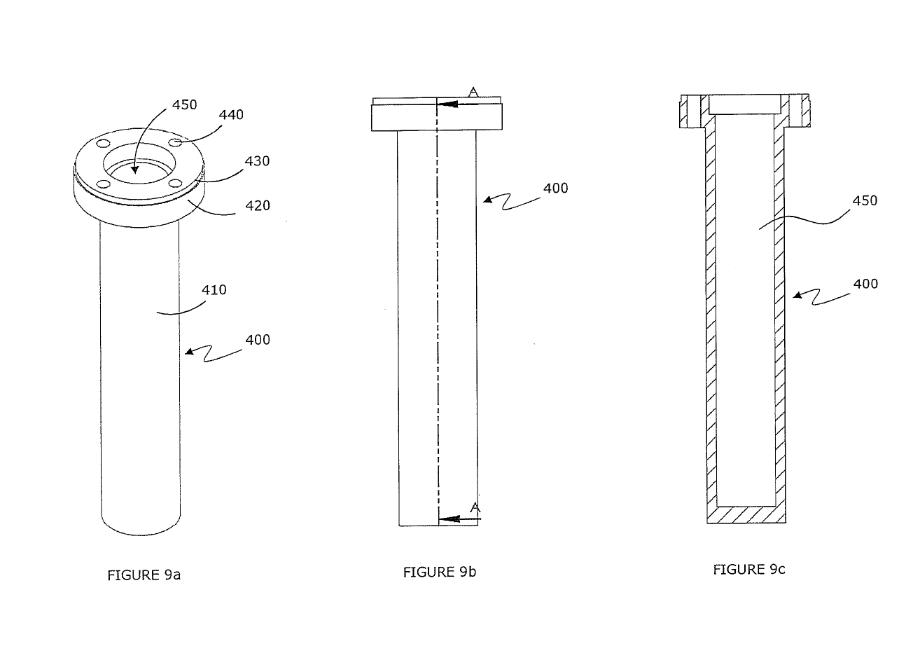

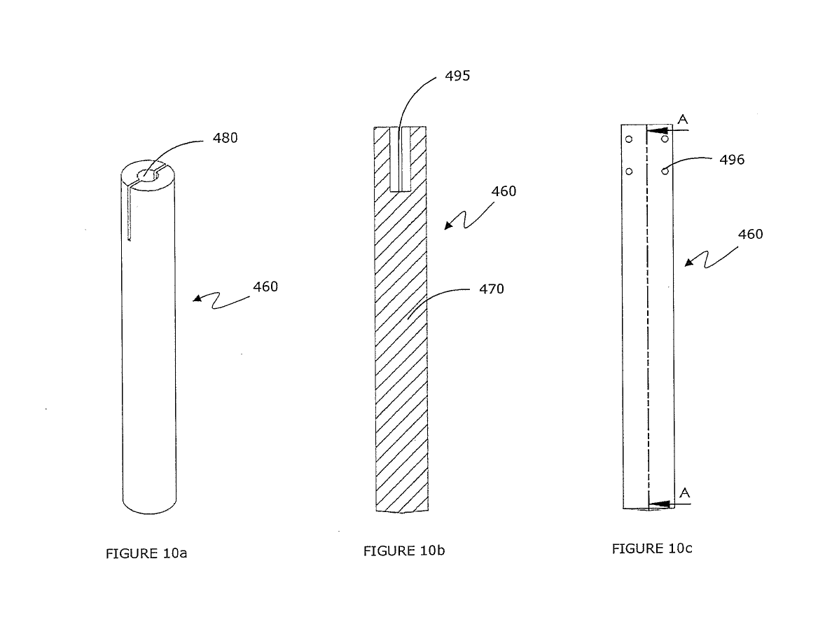

One form of a shear cell for attaching directly to the torque sensor is a cylindrical Couette shear cell. The cylindrical Couette shear cell comprises a cup 400, as shown in FIGS. 9a to 9c, and a spindle 460, as shown in FIGS. 10a to 10c.

The cup 400 of the shear cell comprises a body 410, having a first end at which a collar 420 is located to allow the shear cell to be easily gripped. The collar may comprise a textured surface and/or opposing flat regions to help grip the shear cell.

The cup 400 comprises attachment means for attaching to the torque sensor. In the embodiment shown in FIGS. 9a to 9c, the attachment means comprises an attachment shaft 430 that is adapted to fit within the second recess 258 of the torque sensor and also comprises two or more apertures 440 located on an end face of the attachment shaft and through which pins, screws, or the like can be located and held in place to attach the cup to the torque sensor. The cup also comprises a bore 450 within which a spindle 460 of the shear cell is located. A gap is provided between the outer surface of the spindle and the interior walls of the bore within which a sample can be held. The spindle 460 comprises a spindle body 470, which is preferably substantially cylindrical. An attachment recess 480 is provided at a first end of the spindle and is adapted to receive the second input shaft of the torque sensor therein. In one form, as shown in FIGS. 10a to 10c, the attachment means is in the form of a clamp to clamp the slot closed against the output shaft of the torque sensor. The clamp comprises a slot 495 that extends across the first end of the spindle to form two portions of the spindle at its first end. The clamp also comprises at least one pair of aligned threaded apertures 496, one aperture of the pair being located on each side of the slot. In the embodiment shown in the drawings, four apertures 496 are provided on a first portion of the first end of the spindle. These apertures 496 extend through the first portion and into the slot 495. Aligned apertures are provided on the second portion of the spindle (not shown). These apertures extend from the slot and terminate within the body of the second portion. Threaded fasteners, such as screws or the like, are located within and mesh with the threaded apertures to pull the two parts of the first end of the spindle together to clamp onto the torque sensor output shaft. In another form, not shown, the attachment recess forms a centrally located threaded bore for meshing with a threaded region on the second input shaft of the torque sensor so that the spindle can be screwed onto the torque sensor. However, it should be appreciated that any appropriate attachment means could be used to couple the spindle to the shaft of the torque sensor. The first end of the spindle 460 is coupled to the second input shaft 254 of the torque sensor so that as the drive shaft and torque sensor rotate, the spindle is also caused to rotate within the bore 450 of the cup 400.

The shear cell may be any part or arrangement of parts used to hold a sample for analysis by a rheology or NMR machine. The rheology unit of the invention may be attached to different types of shear cells.

As the motor drives the drive shaft, the shaft of the torque sensor (comprising the input and output shafts at its opposing ends) is caused to rotate simultaneously, transmitting this rotational movement to the spindle of the shear cell so that the spindle is caused to rotate at the same frequency. The sample within the shear cell creates a drag on the spindle, imparting a torque on the torque sensor. The torque sensor transmits this measured value to the control system, reader and/or interface that communicates these to a user of the unit.

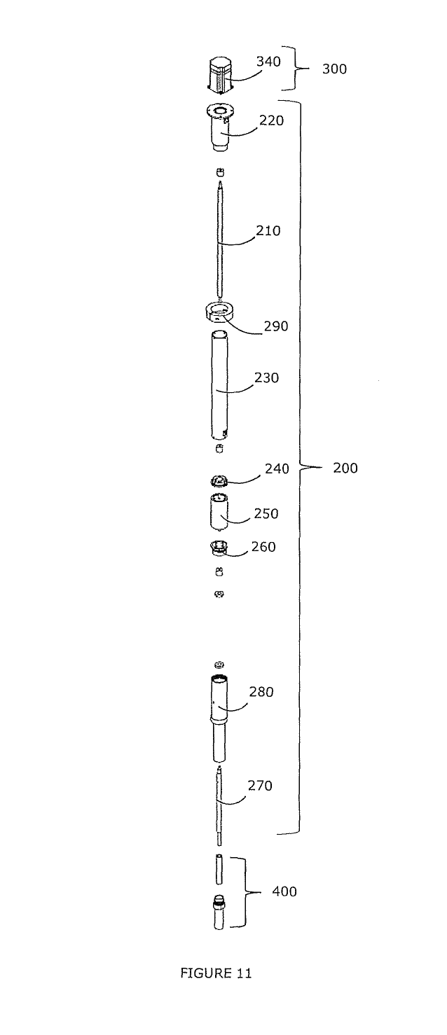

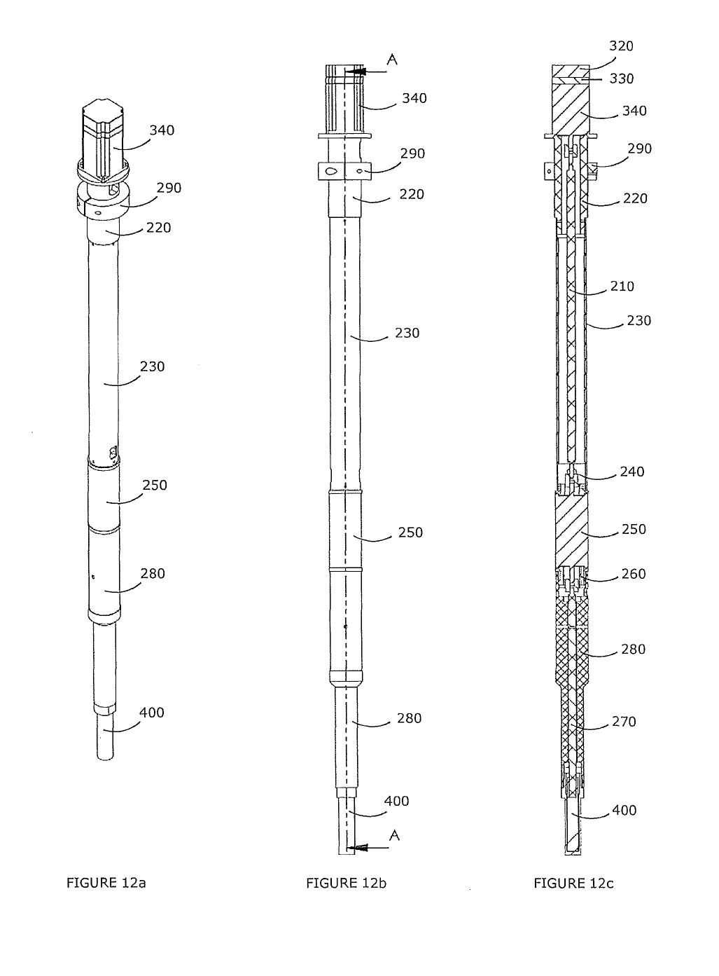

In another form, the measurement device is adapted so that the torque sensor is spaced further away from the shear cell, as shown in FIGS. 11 and 12a to 12c. In this form, the measurement device has the same features as described above except that, instead of being directly attached to a shear cell, the second end of the torque sensor is attached to a drive shaft extension system that is itself attached to a shear cell. The drive shaft extension system is particularly necessary where the torque sensor includes metal parts which need to be spaced from the region inside the bore of the NMR machine with the strongest magnetic field, which Is where the NMR measurements are made.

In one form, the extension system comprises a second torque sensor coupling 260, a extension drive shaft 270, and an extension housing 280. The second input shaft 254 of the torque sensor is adapted to be coupled to the extension drive shaft 270. In addition, the second end of the torque sensor is adapted to attach to the second torque sensor coupling 260 so that the torque sensor 250 is located between the two couplings 240, 260.

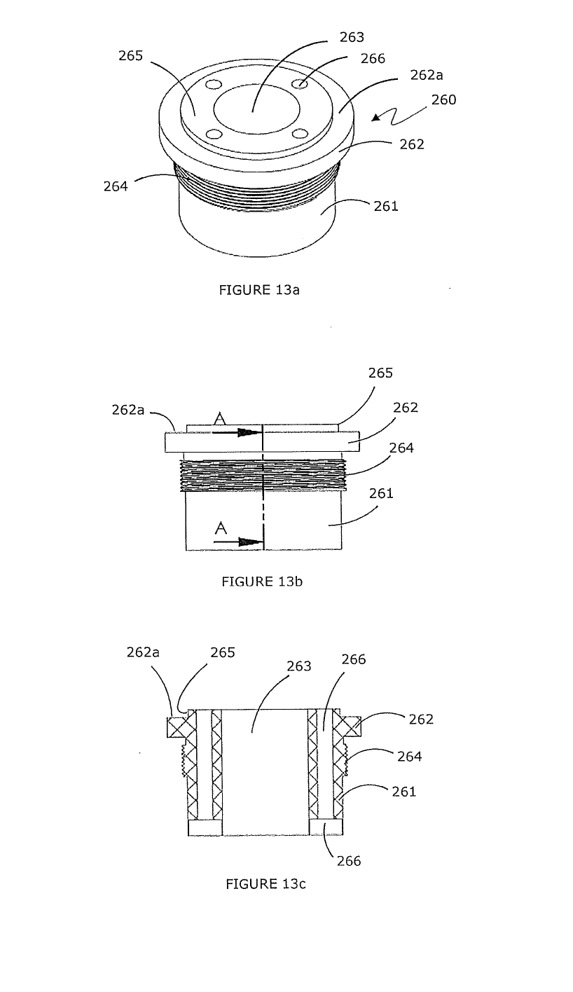

One form of second torque sensor coupling is shown in FIGS. 13a to 13c. In this form, the second torque sensor coupling further comprises an attachment shaft 261, a locating block 265, and a collar 262 positioned between the attachment shaft and the locating block, The collar has a first surface 262a, an opposing second surface 262b, and an outer surface that defines the periperhal edge of the collar. Preferably, the peripheral edge of the collar 262 is substantially circular and has a diameter that is substantially equal to the diameter of the torque sensor to provide a substantially flush join on the exterior surface of the measurement device. A centrally located bore 263 extends along the length of the second torque sensor coupling, through the locating block 265, the collar 262, and the attachment shaft 261.

The second recess 258 formed in the end face of the second end 252b of the torque sensor is adapted to mate with the locating block 265 of the second torque sensor coupling 260, so that the locating block 265 is received within the second recess. The second torque sensor coupling 260 also comprises attachment means to attach the coupling 260 to the torque sensor 250. Preferably, the attachment means comprise one or more apertures 266 that extend between an end surface of the locating block 265 and an end surface of the attachment shaft 261 and that are adapted to align with one or more corresponding apertures (not shown) located in the end face of the second end 252b of the torque sensor 250. A pin, screw or the like (not shown) is positioned within each pair of aligned apertures and is held in place to attach the second torque sensor coupling to the torque sensor.

Preferably, the attachment shaft 261 of the second torque sensor coupling also comprises attachment means for attaching to a first end 282a of the extension housing 280, within which the extension drive shaft 270 is located. In one form, the attachment means comprises a threaded region 264 on an outer surface of the attachment shaft that is adapted to mesh with a corresponding threaded region of the extension housing. Alternatively, the collar 262 and attachment shaft 264 may be integral with each other so that the threaded region is provided within the bore of the second torque sensor coupling and is adapted to mesh with a threaded region provided on the outer surface of the extension housing. It should be appreciated that the attachment means may be of any suitable form and may comprise one or more pairs of aligned apertures formed in the second torque sensor coupling and the extension housing through which a pin, screwn or the like is located and held in place to attach the second torque sensor coupling to the extension housing.

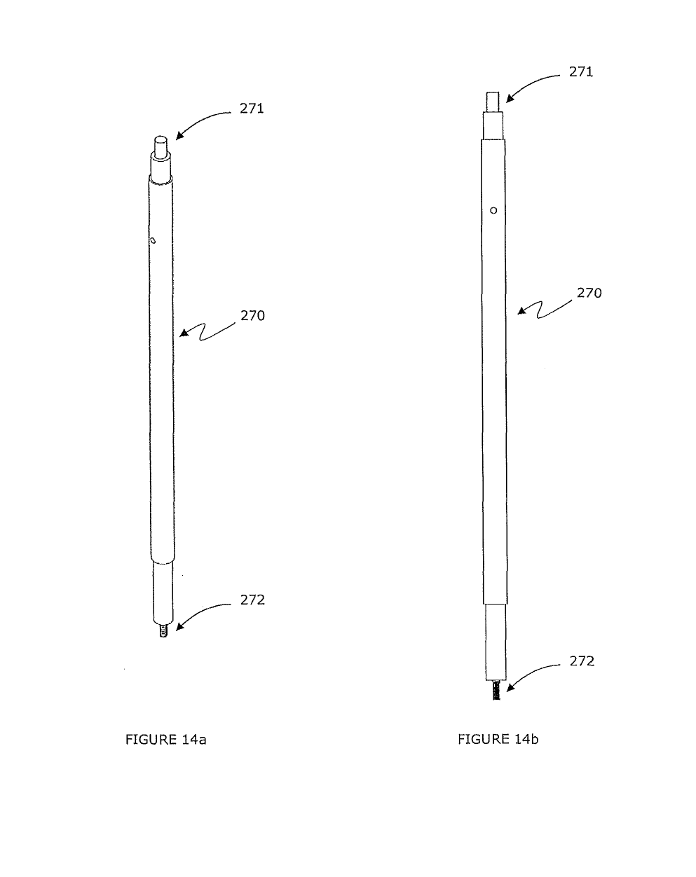

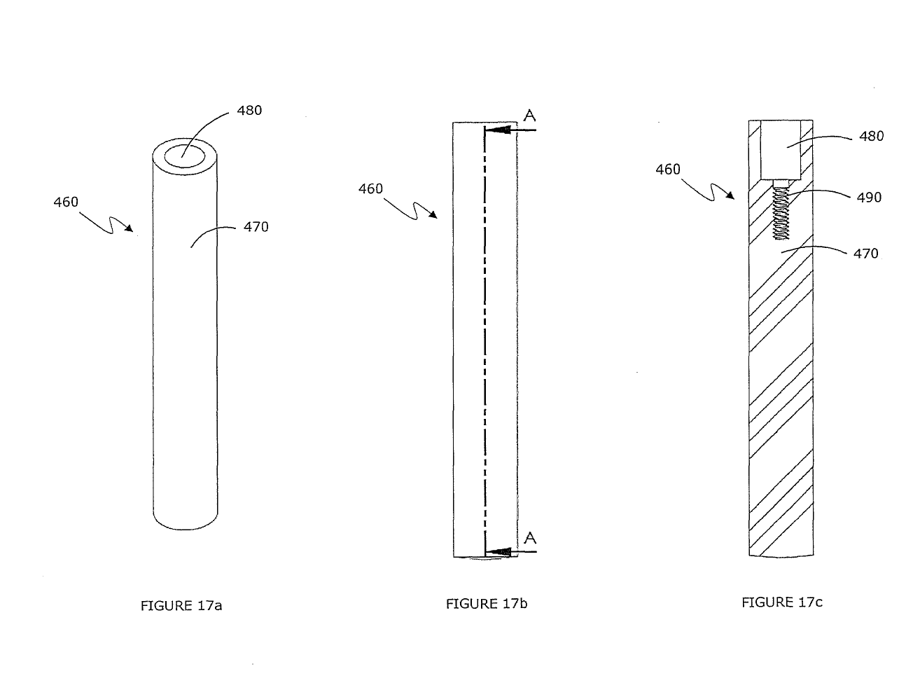

As shown in FIGS. 14a and 14b, the extension drive shaft comprises a first end 271 that is adapted to be attached to the second input shaft 254 of the torque sensor. A second end 272 of the extension drive shaft comprises attachment means to couple the drive shaft to a spindle 460 of a shear cell, such as that shown in FIGS. 17a to 17c.

The spindle 460 comprises a body 470, which is preferably substantially cylindrical, having an attachment recess 480 provided at its first end Preferably, the attachment recess comprises a centrally located threaded bore 490 and the drive shaft extension attachment means comprises a threaded projection that is adapted to mesh with threaded attachment recess of the spindle. In this arrangement, the spindle of the shear cell can be easily screwed onto the second end of the extension drive shaft and held firmly in place.

The extension drive shaft 270 is preferably located substantially concentrically within the central bore 281 of the extension housing 280 and substantially in line with the drive shaft 210. Optionally, bushes or bearings are used to keep the extension drive shaft concentrically located within the extension housing. In this arrangement, the smooth rotational motion of the drive shafts is imposed on the shear cell.

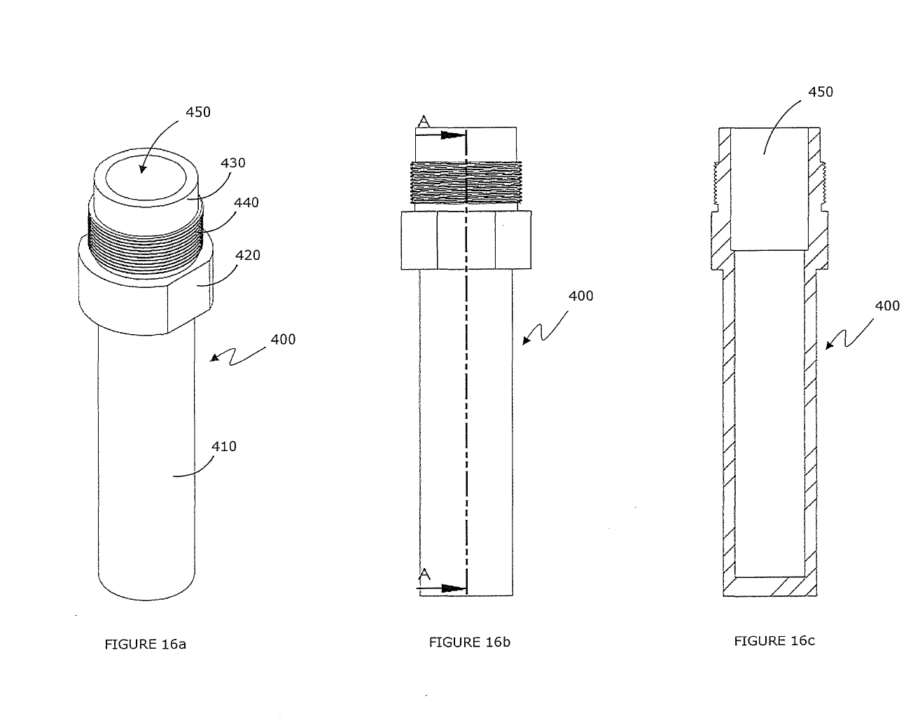

The second end 282b of the drive shaft extension housing is adapted to attach to a cup 400 of a shear cell, the cup being shown in FIGS. 16a to 16c.

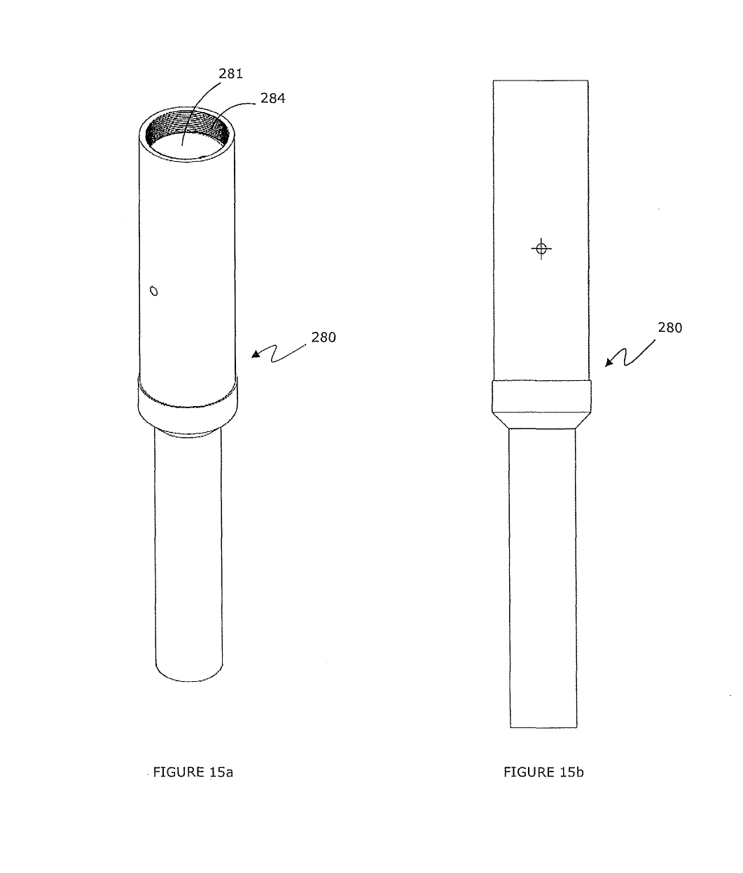

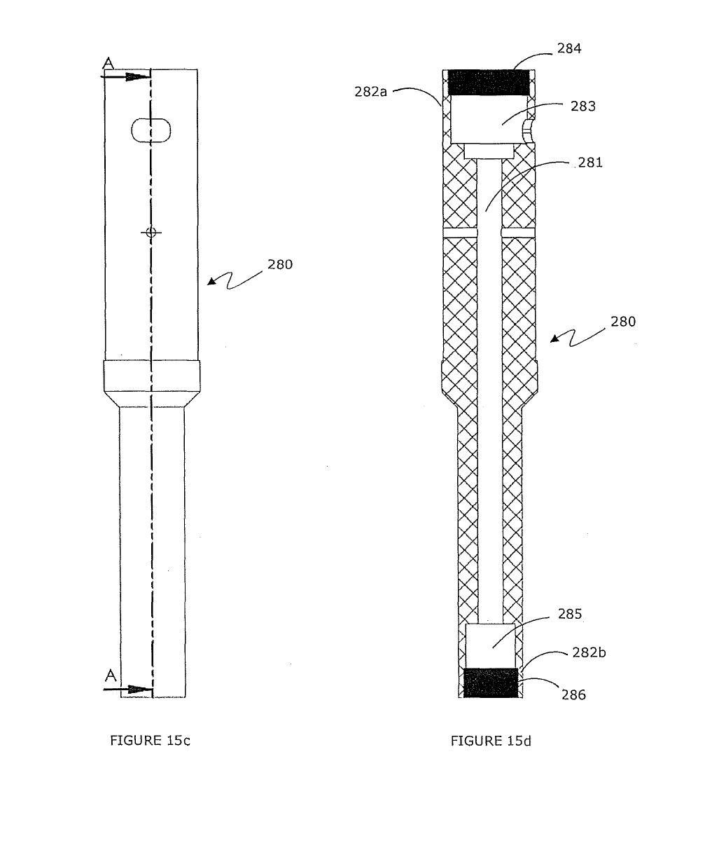

In one form, as shown in FIGS. 15a to 15d, the extension housing 280 comprises a substantially cylindrical body having a central bore 281 that extends along the length of the extension housing and in which the extension drive shaft is positioned. The extension housing also comprises a first end 282a that is adapted to be coupled to the second torque sensor coupling 260. In a preferred form, the bore 281 comprises an enlarged region at its first end that forms an internal collar 283. A threaded region 284 is provided within the collar. The attachment shaft 261 of the second torque sensor coupling 260 is screwed into the first end of the extension housing 280 so that the threaded region 264 of the attachment shaft 261 meshes with the threaded region 284 of the collar 283.

The extension housing 280 also comprises a second end 282b that is adapted to attach to a cup of a shear cell. The extension housing may be attached to the cup using any suitable attachment means. For example, the cup and extension housing may comprise aligned apertures through which a pin, screw, or the like can project and be held in place to attach the two parts together. In another form, the bore 281 of the extension housing 280 comprises an enlarged region at its second end that forms an internal collar 285. A threaded region 286 is provided within the collar and is adapted to mesh with a threaded region of the cup. The internal collar 285 is not only adapted to attach the extension housing to the cup of the shear cell, but is also adapted to control the depth at which the shear cell is inserted within the extension housing.

Again, although one form of shear cell has been shown and described, the shear cell may be any part or arrangement of parts used to hold a sample for analysis by a rheology or NMR machine. The rheology unit of the invention may be attached to different types of shear cells.

In one form, as shown in FIGS. 16a to 16c, the cup of a cylindrical Couette shear cell 400 comprises a body 410 having a collar 420 comprising a gripping region by which the shear cell can be held by a wrench or the like to attach the shear cell to the measurement device. The collar may comprise a textured surface and/or a pair of opposing flat regions to help grip the shear cell. A centrally located bore 450 extends along the length of the cup and is adapted to house the second end 271b of the extension drive shaft and at least a portion of the spindle. An attachment shaft 430 extends at a first end of the shear cell. The attachment shaft comprises attachment means 440 for attaching the cup to the drive shaft extension system. In one form, as shown in FIGS. 16a to 16c, the attachment means comprises a threaded region 440 that is formed on the attachment shaft. The attachment shaft is adapted to be held within the internal collar 285 at the second end of the extension housing by screwing the attachment shaft into the internal collar 285 so that the threaded region 440 of the attachment shaft 430 meshes with the threaded region 286 of the internal collar 285.

Because a portion of the shear cell is held within the interior bore of the extension housing, the shear cell is aligned with the extension housing and is prevented from wobbling relative to the extension housing when in use. Therefore, this arrangement creates a precision alignment between the extension housing and the shear cell.

As the motor drives the drive shaft, the shaft of the torque sensor is caused to rotate simultaneously. The shaft of the torque sensor transmits this rotational movement to the spindle of the shear cell (either directly or via a drive shaft extension system) so that the spindle is caused to rotate. The sample within the shear cell creates a drag on the torque sensor.

The torque sensor is electrically connected to the control system and/or to a reader or interface (not shown). In particular, wires from the torque sensor pass from the torque sensor, through the wire guide channels 244 and 221 and through the bore of the drive shaft housing (or along its exterior) to the control system, reader and/or interface. In effect, the wire guide channels and the bore of the drive shaft housing (or the exterior of the housing) form a continuous wire guide. The torque sensor transmits torque measurements to the control system, reader and/or interface that communicates these to a user of the unit.

Therefore, using the rheology unit of the invention, it is possible to conduct rheo-NMR experiments in which the torque applied to the sample during an experiment can be accurately measured so that the behaviour of a sample can be tested under different torque forces.

Advantages

The invention makes it possible to conduct NMR experiments while the torque response, due to the applied stress in the sample under study, is measured simultaneously. The device provides a rheology instrument to be used within an NMR system.

Although the invention has been described by way of example, it should be appreciated that variations and modifications may be made without departing from the scope of the invention as defined in the claims. Furthermore, where known equivalents exist to specific features, such equivalents are incorporated as if specifically referred in this specification.

Furthermore, although preferred forms of the invention have been described in which one or more parts of the invention are described as fitting within the central bore of one or more other parts of the invention, it should be appreciated that the reverse arrangement could be used without departing from the scope of the invention.

1. A rheological measurement device adapted for use in a bore of an NMR magnet, the measurement device comprising a drive shaft, a drive shaft housing in which the drive shaft is located, and a torque sensor directly or indirectly attached to the drive shaft, wherein the torque sensor is positioned substantially in line with the drive shaft.

2. The measurement device of claim 1, wherein a first end of the torque sensor is indirectly attached to the drive shaft and drive shaft housing by a torque sensor coupling.

3. The measurement device of claim 1, wherein a shear cell is attached to the torque sensor.

4. The measurement device of claim 2, wherein the device further comprises a drive shaft extension system comprising a second torque sensor coupling, and a drive shaft located within an extension housing, wherein the second torque sensor coupling attaches a second end of the torque sensor to the extension drive shaft and the extension housing.

5. The measurement device of claim 4, wherein a shear cell is attached to the second drive shaft.

6. The measurement device of claim 1, wherein the measurement device comprises a wire guide within which wires to connect the torque sensor to a control system can be positioned.

7. A rheology unit comprising a measurement device according to claim 1 and further comprising a drive system comprising a motor coupled to the drive shaft and adapted to rotate the drive shaft.

8. The rheology unit of claim 7, wherein the drive system further comprises a control system comprising a positioning sensor for identifying the orientation of the drive shaft in relation to a drive shaft housing.

9. The rheology unit of claim 8, wherein the positioning sensor is an optical encoder.
